(19) United States
(12) Patent Application Publication
(10) Pub. No.: US 2013/0193566 A1
(43) Pub. Date: Aug. 1, 2013

(54) Integrated Circuit Shielding Film and Manufacturing Method Thereof

(71) Applicants: Chuan-Li Cheng, Taipei City (TW); Hsueh-Tsu Chang, Taipei City (TW)

(72) Inventors: Chuan-Li Cheng, Taipei City (TW); Hsueh-Tsu Chang, Taipei City (TW)

(73) Assignee: CHENMING MOLD IND. CORP., Taipei City (TW)

(21) Appl. No.: 13/611,440

(22) Filed: Sep. 12, 2012

(30) Foreign Application Priority Data
Jan. 31, 2012 (TW) 101103165

(51) Int. Cl. H01L 21/56; H01L 23/28

(52) U.S. Cl. 257/659; 438/118; 257/E21.502; 257/E23.116

(57) ABSTRACT

An integrated circuit shielding film and a manufacturing method thereof. The manufacturing method provides a plate. A stripping glue is coated on the plate. An integrated circuit is disposed on the stripping glue and the stripping glue is deposited on the surface of the integrated circuit. A shielding film is then formed on the integrated circuit by coating operations.

### CROSS-REFERENCE TO RELATED APPLICATION

This application claims the benefit of Taiwan Patent Application No. 101103165, filed on Jan. 31, 2012, in the Taiwan Intellectual Property Office, the disclosure of which is incorporated herein in its entirety by reference.

### FIELD OF THE INVENTION

The present invention relates to an IC shielding film and a manufacturing method thereof, in particular to the IC shielding film and the manufacturing method that coat a stripping glue onto a surface of a plate, so that the IC can be adhered onto the plate and will not fall off during a coating process and a polymer material is sputtered onto the IC by a sputtering method and used as a shielding material for resisting electromagnetic interference.

### BACKGROUND OF THE INVENTION

As science and technology advance, electronic products have increasingly smaller size and increasingly powerful functions. Therefore, the complexity and density of integrated circuits (IC) in the electronic products are higher, and internal transmission lines and power supply units of the IC, or other electronic components with a higher operating frequency on a printed circuit board produce electromagnetic waves, and cause an electromagnetic interference (EMI) with other components, so that the integrated circuit cannot operate normally. Therefore, the effect of the electromagnetic interference on integrated circuit has become a major issue.

In general, a metal housing is usually used to protect a portion of a conventional printed circuit board and guard the printed circuit board from being affected by electromagnetic interference or a sputtering method is used to sputter a polymer shielding material such as a sputtered metal, a carbon fiber or a resin film onto a surface of the IC in order to shield the electromagnetic wave and avoid the electromagnetic interference.

However, the IC generally cannot be attached onto the plate easily during the sputtering process, and the IC may fall off easily to result in a failed sputtering operation. Therefore, it is a main subject for the present invention to overcome the drawbacks of the prior art that the IC falls off easily in a coating process.

### SUMMARY OF THE INVENTION

In view of the shortcomings of the prior art, it is a primary objective of the present invention to provide an IC shielding film and a manufacturing method thereof to overcome the problem of the conventional IC that may fall off easily during a coating process.

To achieve the aforementioned objective, the present invention provides a method of manufacturing an integrated circuit (IC) shielding film, and the IC shielding film manufacturing method comprises steps of: providing a plate; coating a stripping glue on the plate; disposing an IC on the stripping glue, and attaching the stripping glue onto a surface of the IC; and performing a coating operation of the IC to form a shielding film.

Preferably, the method of manufacturing an IC shielding film of the present invention further comprises a step of curing the stripping glue to increase a bonding force between the IC and the plate.

Preferably, the plate further comprises a lower plate, an upper plate, a plurality of conductive pillars disposed on a surface of the lower plate, and a plurality of conductive holes penetrated through a surface of the upper plate.

Preferably, the method of manufacturing an IC shielding film of the present invention further comprises a step of movably latching the plurality of conductive holes with the plurality of conductive pillars to combine the upper plate onto the lower plate.

Preferably, the stripping glue is coated onto the upper plate.

Preferably, the surface of the IC is coupled to one of the combined conductive pillars and the conductive holes when the IC is disposed on the stripping glue.

Preferably, the method of manufacturing an IC shielding film of the present invention further comprises a step of removing the lower plate to separate the conductive pillars from the conductive holes such that the portion of the stripping glue attached to the surface of the IC is stripped off together with the removal of the conductive pillars.

Preferably, the lower plate has at least one positioning pillar, and the upper plate has at least one positioning hole, such that when the lower plate and the upper plate are combined, the positioning pillar is latched into the positioning hole.

Preferably, the shielding film is formed by sputtering a polymer material.

Preferably, the polymer material includes a fiber or a resin.

Preferably, the stripping glue has a thickness from 0.3 μm to 5 μm.

Preferably, the coating operation includes a liquid forming or a vapor deposition.

To achieve the aforementioned objective, the present invention further provides an IC shielding film formed on an IC by the aforementioned method of manufacturing an IC shielding film.

In summation, the method of manufacturing an IC shielding film of the present invention coats the stripping glue onto a surface of the plate to attach an IC onto the plate, and adjust the thickness of the stripping glue according to the requirement of the manufacturing process to facilitate the coating operation of the IC. In addition, the design of the conductive pillars on the lower plate and the conductive holes on the upper plate allows a portion of the stripping glue attached onto the surface of the IC to be stripped off together with the removal of the plurality of conductive pillars to produce a broken hole. The broken hole allows gases in the stripping glue to be discharged and prevents the stripping glue from producing air bubbles or being expanded, so that the IC will not fall off easily during the coating process, and the coating operation can be completed successfully.

### BRIEF DESCRIPTION OF THE DRAWINGS

FIG. 1 is a schematic view of a method of manufacturing an IC shielding film in accordance with a first preferred embodiment of the present invention.

FIG. 2 is a flow chart of a method of manufacturing an IC shielding film in accordance with the first preferred embodiment of the present invention.

FIG. 3 is a first schematic view of a method of manufacturing an IC shielding film in accordance with a second preferred embodiment of the present invention.

FIG. 4 is a second schematic view of a method of manufacturing an IC shielding film in accordance with the second preferred embodiment of the present invention.

FIG. 5 is a third schematic view of a method of manufacturing an IC shielding film in accordance with the second preferred embodiment of the present invention.

FIG. 6 is a fourth schematic view of a method of manufacturing an IC shielding film in accordance with the second preferred embodiment of the present invention.

FIG. 7 is a fifth schematic view of a method of manufacturing an IC shielding film in accordance with the second preferred embodiment of the present invention.

FIG. 8 is a flow chart of a method of manufacturing an IC shielding film in accordance with the second preferred embodiment of the present invention.

### DESCRIPTION OF THE PREFERRED EMBODIMENTS

The technical characteristics of the present invention will become apparent with the detailed description of the preferred embodiments accompanied with the illustration of related drawings as follows. It is noteworthy to point out that the drawings not necessarily drawn according to the actual scale or exact precision, since the drawings are provided for the purpose of illustrating the invention and complementing the description of the specification, but not intended for limiting the scope of the invention.

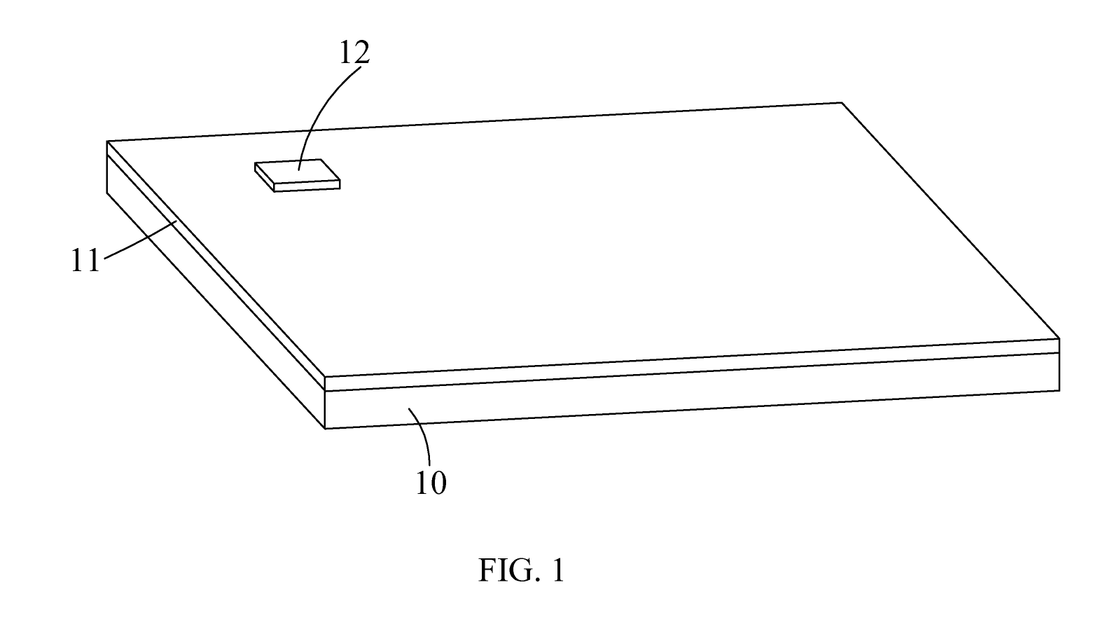

With reference to FIG. 1, in which a schematic view of a method of manufacturing an IC shielding film in accordance with the first preferred embodiment of the present invention, the method of manufacturing an IC shielding film provides a plate 10 first, and the plate 10 is made of aluminum alloy, plastic or any other material that cannot be melted easily by heat. And then, a stripping glue 11 is coated onto the plate 10 by a coating or printing method. Wherein, the stripping glue 11 has a thickness from 0.3 μm to 5 μm, or the thickness can be adjusted according to the requirements of the manufacturing process, and the invention is not limited to the aforementioned thickness only. And then, an IC 12 is placed on the stripping glue 11, and the stripping glue 11 is attached onto a surface of the IC 12 to couple a surface of the IC 12 onto the plate 10.

Further, the stripping glue 11 is cured to increase the boding force between the IC 12 and the plate 10, so that the IC 12 will not fall off easily during the coating operation due to insufficient bonding force that causes a failed sputtering. After the aforementioned steps take place, the IC 12 together with the plate 10 are placed a chamber of an equipment for performing a shield coating operation of the IC 12 to form a shielding film. Wherein, the shielding film of the IC 12 can be made of a polymer material which is formed by sputtering a shielding material, and the polymer material includes a fiber, such as polyester fiber or a nylon fiber, and the polymer material includes a resin, such as an epoxy resin or a phenolic resin, but the invention is not limited to these resins only. In addition, the coating operation includes a liquid forming or a vapor deposition.

After the coating operation is completed, the IC 12 is removed, and the stripping glue 11 on the surface of the plate 10 is stripped off, so that the plate 10 can be used repeatedly for the next coating operation.

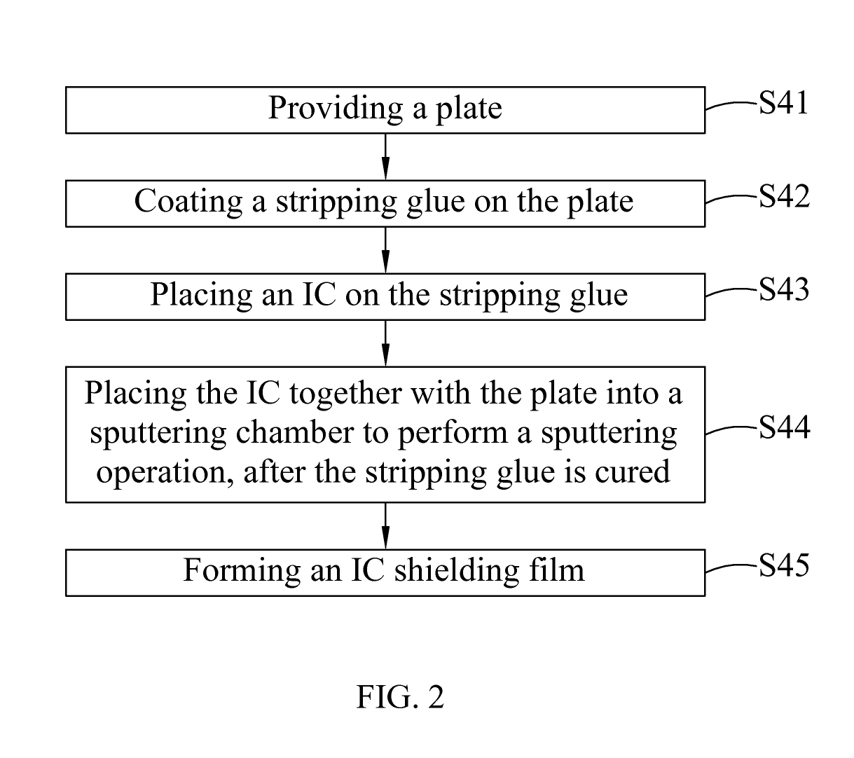

With reference to FIG. 2, in which a flow chart of a method of manufacturing an IC shielding film in accordance with the first preferred embodiment of the present invention, the method of manufacturing an IC shielding film comprises the following steps:

S41: Providing a plate which can be made of aluminum alloy or plastic.

S42: Coating a stripping glue on the plate by a coating or printing method.

S43: Placing an IC to be sputtered on the stripping glue.

S44: Placing the IC together with the plate into a sputtering chamber to perform a sputtering operation, after the stripping glue is cured.

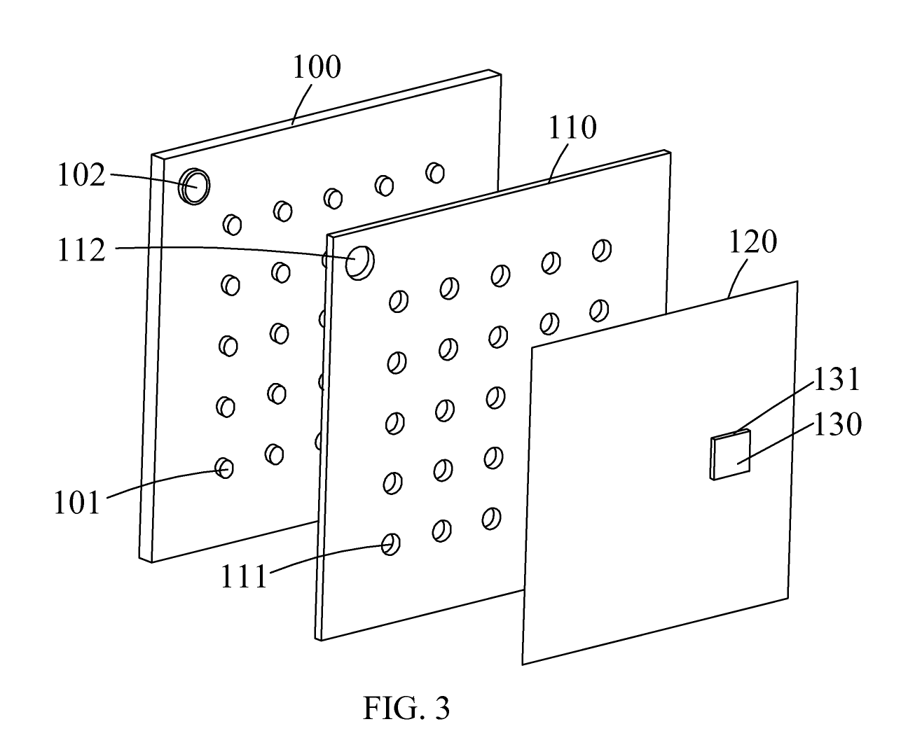

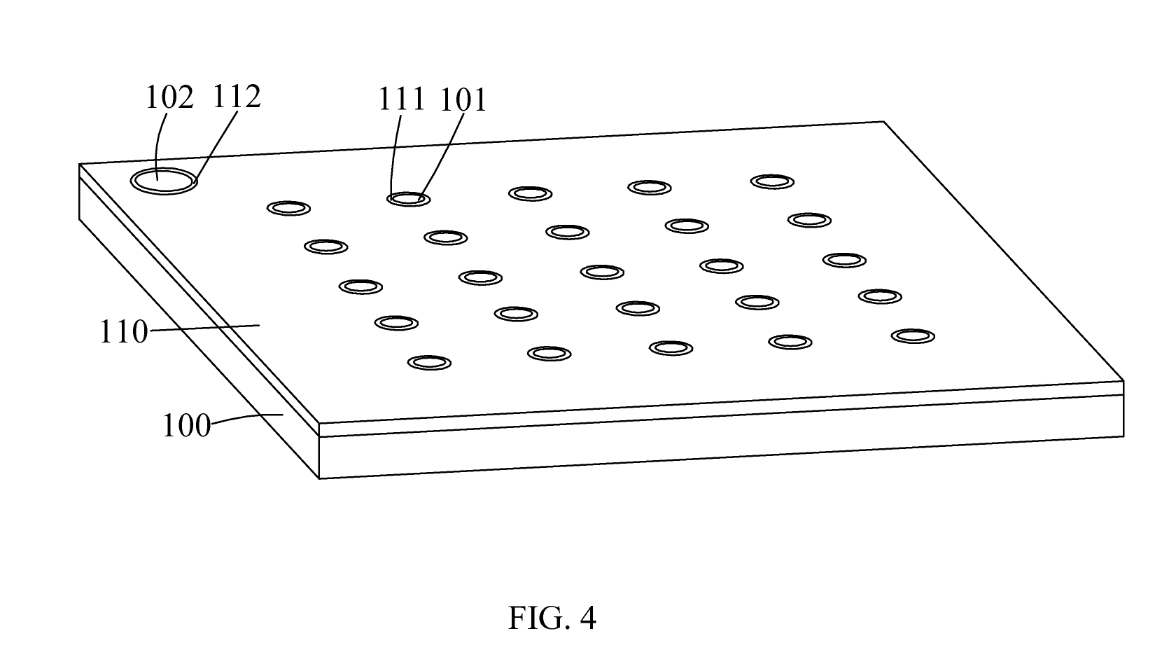

With reference to FIGS. 3 to 7, in which the first to the fifth schematic views of a method of manufacturing an IC shielding film of the present invention respectively, the method of manufacturing an IC shielding film comprises the steps of: providing a lower plate 100 first, wherein the lower plate 100 includes a plurality of conductive pillars 101 and at least one positioning pillar 102, and the conductive pillars 101 and the positioning pillar 102 are installed on a surface of the lower plate 100; and then providing an upper plate 110, wherein the upper plate 110 includes a plurality of conductive holes 111 and the at least one positioning hole 112, and the conductive holes 111 and the positioning hole 112 are holes penetrating through a surface of the upper plate 110. Wherein, the lower plate 100 and the upper plate 110 can be made of aluminum alloy, plastic or any other material that cannot be melted easily by heat. When the upper plate 110 is combined onto the lower plate 100, the at least one positioning pillar 102 of the lower plate 100 is aligned precisely with the at least one positioning hole 112 of the upper plate 110 to facilitate combining the upper plate 110 and the lower plate 100 successfully. And then, the at least one positioning pillar 102 is latched into the at least one positioning hole 112, such that the plurality of conductive holes 111 of the upper plate 110 and the plurality of conductive pillars 101 of the lower plate 100 are latched respectively, and the upper plate 110 and the lower plate 100 can be combined with each other as shown in FIG. 4. Wherein, the latch between the at least one positioning pillar 102 and the at least one positioning hole 112 can fix the upper plate 110 onto the lower plate 100 securely to prevent them from sliding with respect to each other, when the lower plate 100 and the upper plate 110 are combined.

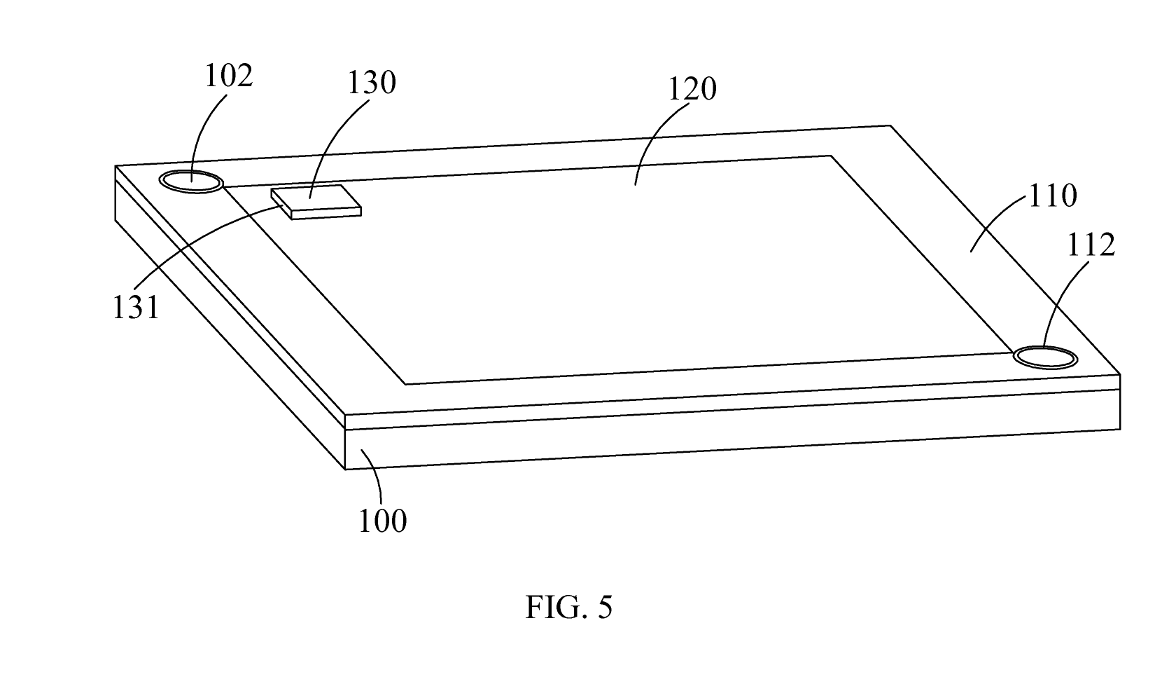

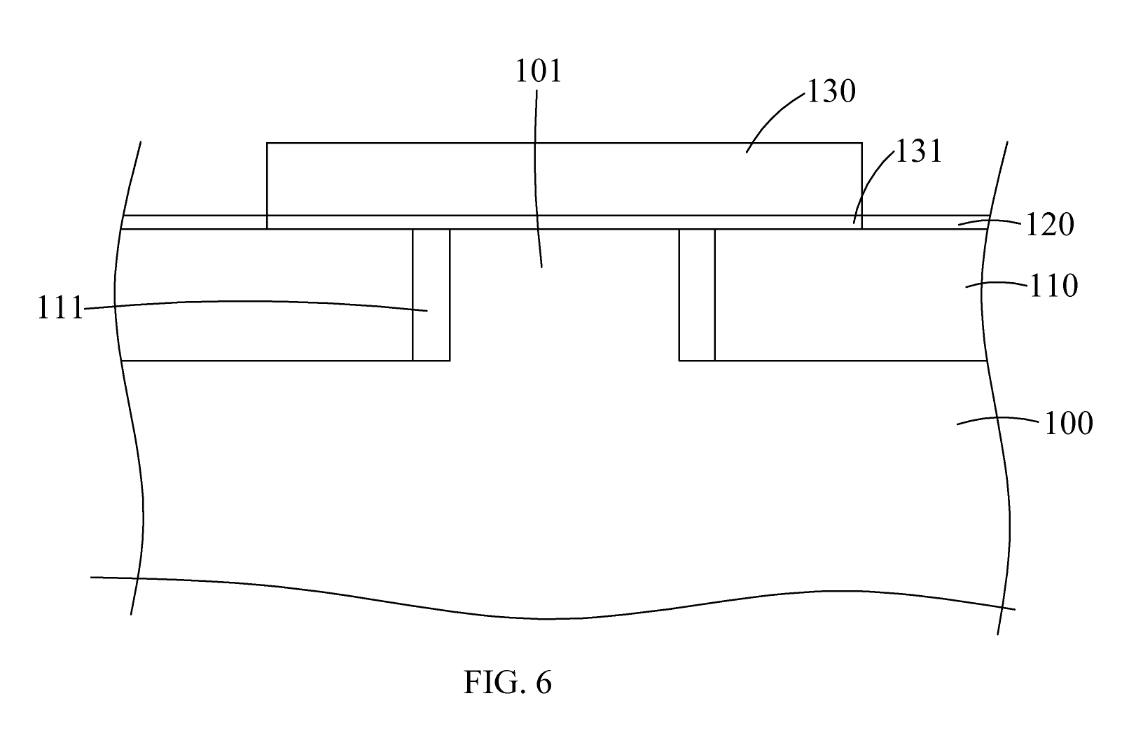

After the upper plate 110 is combined onto the lower plate 100, a stripping glue 120 is coated or printed onto the upper plate 110, so that the stripping glue 120 is covered and combined to the conductive pillars 101 and the conductive hole 111. Wherein, the stripping glue 120 has a thickness from 0.3 μm to 5 μm, and the thickness can be adjusted according to the user requirements, but it is not limited to the aforementioned thickness only. And then, the IC 130 is placed onto the stripping glue 120, and the stripping glue 120 attached onto a surface of the IC 130 allows the surface of the IC 130 to be combined onto the upper plate 110 and the installation position of the IC 130 corresponds to one of the combined plurality of conductive pillars 101 and plurality of conductive holes 111 as shown in FIG. 5 and whose cross-sectional view is shown in FIG. 6. Further, the stripping glue 120 is cured to increase the bonding force between the IC 130 and the upper plate 110, so that the IC 130 will not fall off easily during the coating operation due to an insufficient bonding force, thus resulting in a failed sputtering. Wherein, the stripping glue 120 is attached onto the surface of the IC 130, while covering a copper foil 131 of the IC 130, so that a shielding area is formed on a side of the IC 130.

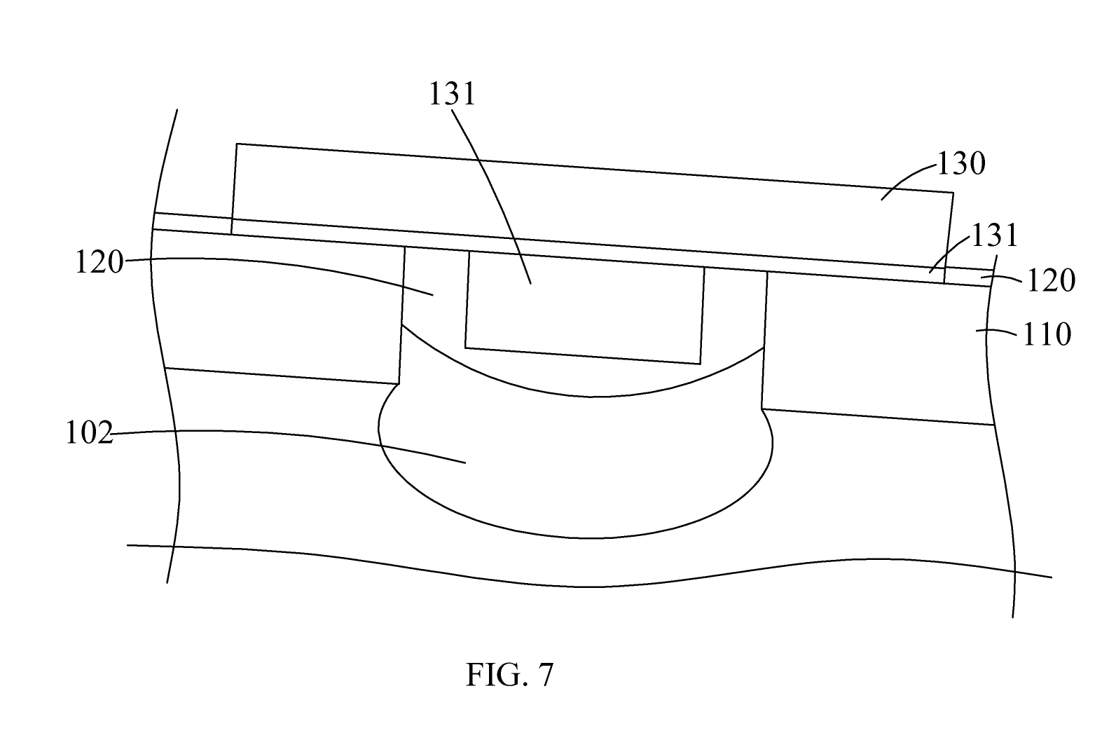

Finally, the IC 130 is attached securely onto the upper plate 110, and the lower plate 100 is removed, so that the plurality of conductive pillars 101 and the plurality of conductive holes 111 are separated from one another. Now, a portion of the stripping glue 120 attached onto the surface of the IC 130 will be stripped away together with the removal of the plurality of conductive pillars 101 to produce a broken hole, so that a portion or the whole of the copper foil 131 will be exposed, and gases in the stripping glue 120 are discharged from the broken hole to prevent the stripping glue 120 from producing air bubbles or being expanded, which will cause a fall-off of the IC 130 or affect the coating operation as shown in FIG. 7.

After the aforementioned steps are executed, the IC 130 together with the upper plate 110 can be placed into a chamber of an equipment to perform a shielding coating operation of the IC 130 to form a shielding film. Wherein, the shielding film of the IC 130 can be formed by sputtering a polymer material which is used as a shielding material, and the polymer material includes but not limited to a fiber such as a polyester fiber and a nylon fiber, or a resin such as an epoxy resin and a phenolic resin. The coating operation can be a liquid forming or a vapor deposition. The vapor deposition can be a chemical vapor deposition (CVD) or a physical vapor deposition (PVD). The physical vapor deposition (PVD) includes a thermal evaporation deposition, a plasma sputtering, or ion beam sputtering. Wherein, the principle of the physical vapor deposition is to heat and sublimate the shielding material into a gas, and then the atoms, molecules or ions of the gas are accelerated to pass through a highly vacuumed space to attach the vaporized shielding material onto a surface of the IC 130 to form a thin film on the surface to be coated, and the thin film is used for the purpose of resisting electromagnetic interference.

After the coating operation is completed, the IC 130 can be removed, and the stripping glue 120 attached onto the surface of the upper plate 110 and the plurality of conductive pillars 111 of the lower plate 100 is stripped off, so that the upper plate 110 and the lower plate 100 can be used repeated for the next coating operation.

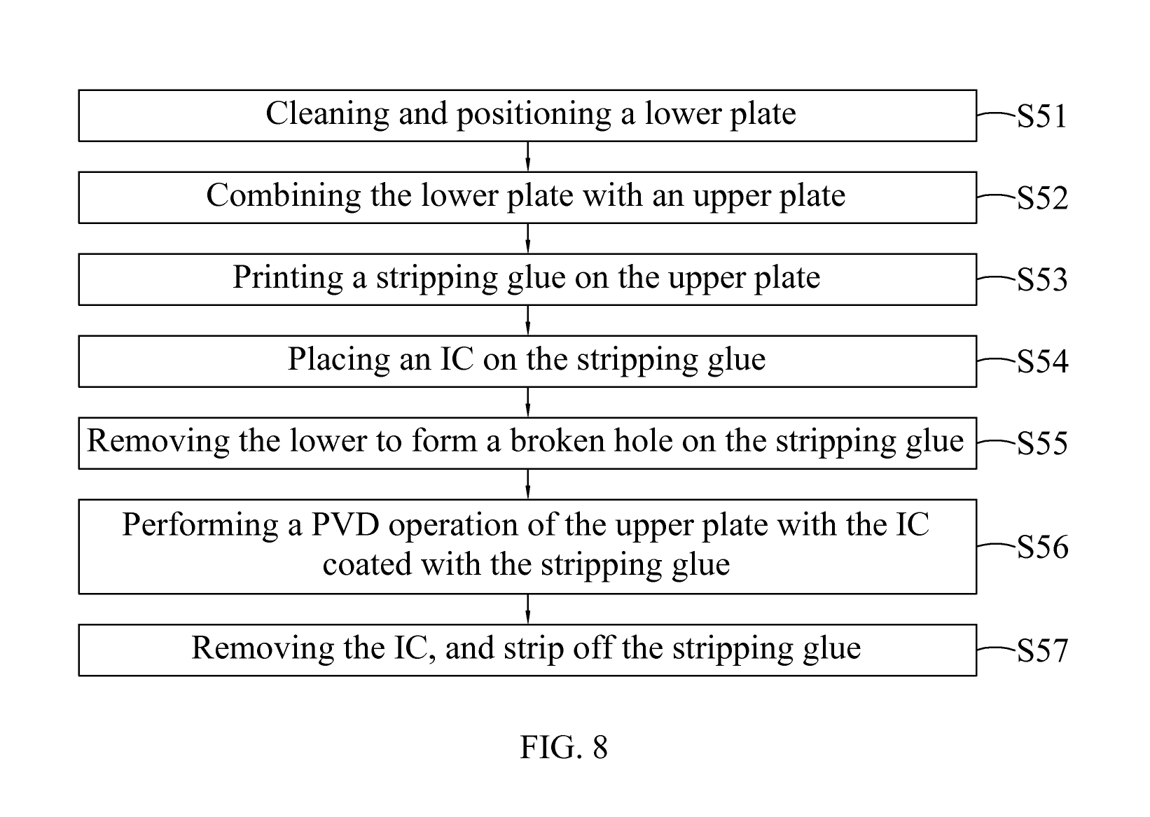

With reference to FIG. 8, in which a flow chart of a method of manufacturing an IC shielding film in accordance with the second preferred embodiment of the present invention, the IC shielding film manufacturing method comprises the following steps:

S51: Providing a lower plate for a positioning purpose, wherein the lower plate is made of aluminum alloy or plastic.

S52: Providing an upper plate which is installed on the lower plate, and made of a material including but not limited to aluminum alloy and plastic.

S53: Providing a stripping glue formed on the upper plate by a coating or printing method.

S54: Placing an IC to be sputtered on the stripping glue.

S55: Removing the lower plate after the IC is attached securely onto the upper plate to separate the plurality of conductive pillars from the plurality of conductive holes, such that a broken hole is formed on the stripping glue on a surface of the IC.

S56: Placing the IC without the lower plate into a vacuum shielding film chamber to perform a coating operation of the IC to form a shielding film.

S57: Removing the IC after the coating operation is completed, and strip the stripping glue from the surface of the upper plate to form the IC shielding film.

In the method of manufacturing an IC shielding film of the present invention, the stripping glue is coated on a surface of the plate to attached the IC onto the plate securely, so that the IC will not fall off easily during the coating process, and the thickness of the stripping glue can be adjusted according to the requirements of the manufacturing process to facilitate performing the coating operation of the IC.

In summation of the description above, the present invention breaks through the prior, achieves the expected effects, and complies with the patent application requirements, and thus is duly filed for patent application.

While the invention has been described by means of specific embodiments, numerous modifications and variations could be made thereto by those skilled in the art without departing from the scope and spirit of the invention set forth in the claims.

What is claimed is:

1. A method of manufacturing an integrated circuit (IC) shielding film, comprising steps of:
providing a plate;
coating a stripping glue on the plate;
disposing an IC on the stripping glue, and attaching the stripping glue onto a surface of the IC; and
performing a coating operation of the IC to form a shielding film.

2. The method of manufacturing an IC shielding film of claim 1, further comprising a step of curing the stripping glue to increase a bonding force between the IC and the plate.

3. The method of manufacturing an IC shielding film of claim 1, wherein the plate further comprises a lower plate, an upper plate, a plurality of conductive pillars disposed on a surface of the lower plate, and a plurality of conductive holes penetrated through a surface of the upper plate, and the method further comprises a step of movably latching the plurality of conductive holes with the plurality of conductive pillars to combine the upper plate onto the lower plate.

4. The method of manufacturing an IC shielding film of claim 3, wherein the stripping glue is coated onto the upper plate.

5. The method of manufacturing an IC shielding film of claim 4, wherein the surface of the IC is coupled to one of the combined conductive pillars and the conductive holes when the IC is disposed on the stripping glue.

6. The method of manufacturing an IC shielding film of claim 5, further comprising a step of removing the lower plate to separate the conductive pillars from the conductive holes such that the portion of the stripping glue attached to the surface of the IC is stripped off together with the removal of the conductive pillars.

7. The method of manufacturing an IC shielding film of claim 3, wherein the lower plate has at least one positioning pillar, and the upper plate has at least one positioning hole, such that when the lower plate and the upper plate are combined, the positioning pillar is latched into the positioning hole.

8. The method of manufacturing an IC shielding film of claim 1, wherein the shielding film is formed by sputtering a polymer material.

9. The method of manufacturing an IC shielding film of claim 8, wherein the polymer material includes a fiber or a resin.

10. The method of manufacturing an IC shielding film of claim 1, wherein the stripping glue has a thickness from 0.3 μm to 5 μm.

11. The method of manufacturing an IC shielding film of claim 1, wherein the coating operation includes a liquid forming or a vapor deposition.

12. An IC shielding film, formed on an IC by an IC shielding film manufacturing method, the manufacturing method comprising steps of:
providing a plate;
coating a stripping glue on the plate;
disposing an IC on the stripping glue, and attaching the stripping glue onto a surface of the IC; and
performing a coating operation of the IC to form a shielding film.

13. The IC shielding film of claim 12, wherein the IC shielding film manufacturing method further comprises a step of curing the stripping glue to increase a bonding force between the IC and the plate.

14. The IC shielding film of claim 12, wherein the plate further comprises a lower plate, an upper plate, a plurality of conductive pillars disposed on a surface of the lower plate, and a plurality of conductive holes penetrated through a surface of the upper plate, and the method further comprises a step of movably latching the plurality of conductive holes with the plurality of conductive pillars to combine the upper plate onto the lower plate.

15. The IC shielding film of claim 14, wherein the stripping glue is coated onto the upper plate.

16. The IC shielding film of claim 15, wherein the surface of the IC is coupled to one of the combined conductive pillars and the conductive holes when the IC is disposed on the stripping glue.

17. The IC shielding film of claim 16, wherein the IC shielding film manufacturing method further comprises a step of removing the lower plate to separate the conductive pillars from the conductive holes such that the portion of the stripping glue attached to the surface of the IC is stripped off together with the removal of the conductive pillars.

18. The IC shielding film of claim 14, wherein the lower plate has at least one positioning pillar, and the upper plate has at least one positioning hole, such that when the lower plate and the upper plate are combined, the positioning pillar is latched into the positioning hole.

19. The IC shielding film of claim 12, wherein the shielding film is formed by sputtering a polymer material.

20. The IC shielding film of claim 12, wherein the stripping glue has a thickness from 0.3 μm to 5 μm.
